(19) United States
(12) Patent Application Publication
(10) Pub. No.: US 2008/0182347 A1
(43) Pub. Date: Jul. 31, 2008

(54) Methods for monitoring ion implant process in bond and cleave, silicon-on-insulator (SOI) wafer manufacturing

(75) Inventors: Kenneth Steeples, Billerica, MA (US); Adam Bertuch, Salem, MA (US); Edward Tsidilkovski, Chelmsford, MA (US)

Correspondence Address: Kirkpatrick & Lockhart Preston Gates Ellis LLP;(FORMERLY KIRKPATRICK & LOCKHART NICHOLSON GRAHAM), STATE STREET FINANCIAL CENTER, One Lincoln Street, BOSTON, MA, 02111-2950, US

(73) Assignee: QC Solutions, Inc., Billerica, MA (US)

(21) Appl. No.: 11/998,901

(22) Filed: Dec. 3, 2007

Related U.S. Application Data
(60) Provisional application No. 60/872,183, filed on Dec. 1, 2006.

(51) Int. Cl. H01L 21/66; B05C 11/00

(52) U.S. Cl. 438/14; 118/712; 257/E21.521

(57) ABSTRACT

A method of in-line characterization of ion implant process, during the SOI bond and cleave manufacturing or engineered silicon layer fabrication. In one embodiment, the method includes the steps of illuminating the engineered donor wafer using a modulated light source; performing a non-contact SPV measurement on the silicon wafer; measuring a dynamic charge (Q_{d}) in response to implant induced crystal damage; and determining the accuracy and uniformity of the value of an implant parameter in response to the dynamic charge. In another embodiment, In another embodiment, the step of determining utilizes the equation V_{PV}≈kTΦ/ωQₙₑₜ where V_{PV} is photo voltage generated in the implanted wafer, Φ is a light flux of the modulated light source, T is temperature of the wafer, and ω is a light modulation frequency of the modulated light source.

### CROSS REFERENCE TO RELATED APPLICATIONS

This application claims priority to and the benefit of U.S. provisional patent application No. 60/872,183, filed on Dec. 1, 2006, the entire disclosure of which is incorporated by reference herein.

### FIELD OF THE INVENTION

The invention relates to the field of semiconductor wafer manufacturing and testing, and more specifically, to a method for characterizing ion implant in semiconductor wafers during the bond and cleave manufacturing of engineered substrate wafers.

### BACKGROUND OF THE INVENTION

The process of manufacturing silicon chips typically includes a step of implanting ions in a silicon substrate. During the implantation process, implanted ions create, in the silicon substrate, areas of crystalline damage associated with displaced lattice atoms. These knocked out atoms make so-called Frenkel pairs, which consist of a silicon atom in an interstitial site and a vacancy. Vacancies and interstitial atoms are crystalline point defects that have energies far below the edges of the silicon band gap. Therefore, these defects are very effective traps and recombination centers for the mobile charge carriers, resulting in a reduction of carrier lifetime. The density distribution of these point defects is related to the implant process parameters, such as implantation dose, energy and angle.

Because substantial defects on a wafer can cause the wafer to be unusable, there is a need of a system and method for characterizing implanted ion concentration in an engineered donor wafer. The disclosed invention provides a solution for this need.

### SUMMARY OF THE INVENTION

In one aspect, the invention relates to a method of characterizing implanted ion concentration in an engineered donor wafer. In one embodiment, the method includes the steps of illuminating the engineered donor wafer using a modulated light source; performing a non-contact SPV measurement on the silicon wafer; measuring a dynamic charge (Q_{d}) in response to implant induced crystal damage; and determining the accuracy and uniformity of the value of an implant parameter in response to the dynamic charge.

In another embodiment, the engineered donor wafer is a silicon-on-insulator wafer. In another embodiment, the step of illuminating takes place before a bond and cleave process. In another embodiment, ion is selected from the group consisting of hydrogen, helium, argon, silicon, germanium and oxygen. In another embodiment, the implanted wafer is measured through a layer selected from the group consisting of a surface oxide layer, a nitride layer and a photo-resist layer. In another embodiment, the implant parameter is selected from the group consisting of implant dose, energy and angle. In another embodiment, the step of determining utilizes the equation V_{PV}≈kTΦ/ωQₙₑₜ where V_{PV} is photo voltage generated in the implanted wafer, Φ is a light flux of the modulated light source, T is temperature of the wafer, and ω is a light modulation frequency of the modulated light source. In another embodiment, the implant parameter is uniformity and the method further includes the step of measuring the thermal effects of implant process non-uniformities.

In another aspect, the invention relates to a system for characterizing implanted ion concentration in an engineered donor wafer. In one embodiment, the system includes a modulated light source adapted to illuminate the engineered donor wafer; a SPV measurement component adapted to perform a non-contact SPV measurement on the silicon wafer; a charge measurement component adapted to measure a dynamic charge (Q_{d}) in response to implant induced crystal damage; and a processor adapted to determine the accuracy and uniformity of the value of an implant parameter in response to the dynamic charge.

In another embodiment, a system for characterizing implanted ion concentration in an engineered donor wafer is provided. The system includes means for illuminating the engineered donor wafer; means for performing a non-contact SPV measurement on the silicon wafer; means for measuring a dynamic charge (Q_{d}) in response to implant induced crystal damage; and means for determining the accuracy and uniformity of the value of an implant parameter in response to the dynamic charge.

### BRIEF DESCRIPTION OF THE DRAWINGS

These embodiments and process aspects of this invention will be readily apparent from the detailed description below and the appended drawings, which are meant to illustrate and not to limit the invention. The process steps for SOI bond and cleave manufacturing include implant monitoring after the implant step using the developed ac-SPV technique.

FIG. 1 is a schematic representation of one form of apparatus which may be employed to measure the photo-induced surface voltage of a specimen of semiconductor material in accordance with the present invention;

FIG. 2 is a series of diagrams presenting an in-line ac-SPV measurement scheme for a bond and cleave technique, SOI wafer manufacturing process, according to an embodiment of the invention;

FIG. 3 is a diagram illustrating the correlation of measured dynamic charge (Q_{d}) to implant dose for hydrogen ion implantation; and

FIG. 4 is a diagram illustrating the correlation of measured dynamic charge (Q_{d}) to implant dose for helium ion implantation.

### DETAILED DESCRIPTION

The present invention will be more completely understood through the following detailed description, which should be read in conjunction with the attached drawings. In this description, like numbers refer to similar elements within various embodiments of the present invention. Within this detailed description, the claimed invention will be explained with respect to preferred embodiments. However, the skilled artisan will readily appreciate that the methods and systems described herein are merely exemplary and that variations can be made without departing from the spirit and scope of the invention.

In general, the invention is related to a method of characterizing ion implanted semiconductor wafers during the bond and cleave manufacturing process for silicon-on-insulator (SOI) wafers. This characterization can be used to classify SOI wafers as either suitable or unsuitable for further processing toward the production of silicon based electrical circuits. The application of an alternating current surface photo voltage (ac-SPV) technique for ion implantation monitoring is based substantially on a photo carrier lifetime measurement. By introducing light into a wafer, parameters can be measured that correlate with the implanted ion concentration present in the wafer. In one aspect of the invention, the method of characterizing ions implanted into a silicon donor wafer during SOI or an engineered substrate manufacturing is similar to the ac-SPV characterization of ion species, such as boron, phosphorus, and arsenic, which are traditionally used in the ion implantation step for silicon chip manufacturing.

The SPV-based lifetime measurement, as described in U.S. Pat. No. 6,911,350, yields information about defect concentration and in-depth distribution that allows monitoring of all the critical parameters of the implantation process. The only known limitation to the method is related to the damage saturation regime when the defect concentration no longer follows the change in the implantation dose. In that case, an annealing step is required for the application of the SPV technique for implant monitoring.

In the SPV method, as disclosed in U.S. Pat. No. 6,911,350, a beam of light is directed at a region of the surface of a specimen of semiconductor material and the photo-induced change in electrical potential at the surface is measured. The wavelength of the illuminating light beam is selected to be shorter than the wavelength of light corresponding to the energy gap of the semiconductor material undergoing testing. The intensity of the light beam is modulated, with both the intensity of the light and the frequency of modulation being selected such that the resulting AC component of the induced photovoltage is directly proportional to the intensity of light and inversely proportional to the frequency of modulation.

When measured under these conditions, the AC component of the surface photovoltage (SPV), designated δVₛ, is proportional to the reciprocal of the semiconductor space-charge capacitance, C_{sc}. When the surface of the specimen is illuminated uniformly, the relationship between the surface photovoltage (SPV) and the space-charge capacitance is given, at sufficiently high frequencies of light modulation, by the relation:

$$δ {V}_{s} = \frac{φ ( 1 - R )}{Kf} {qC}_{SC}^{- 1}$$

where φ is the incident photon flux, R is the reflection coefficient of the semiconductor specimen, f is the frequency at which the light is modulated, and q is the elementary charge. The constant K is equal to 4 for a square wave modulation of the light intensity and is equal to 2π for sinusoidal modulation.

In the above referenced patent, only a uniform configuration is considered in which the area of the sensor is at least the same size as the semiconductor wafer and the entire area of the specimen is uniformly illuminated. When only a portion of the semiconductor specimen surface is coupled to the sensor, that is, when the sensor is smaller than the wafer, and when the semiconductor surface uniformly illuminated in that area is coupled to the sensor, the surface photovoltage, δVₛ, may be determined from the measured signal, δVₘ, according to the relationships:

Re(δVₛ)=Re(δVₘ)−(1+C_{L}/Cₚ)+Im(δVₘ)·(ω·Cₚ·R_{L})⁻¹

Im(δVₛ)=Im(δVₘ)·(1+C_{L}/Cₚ)−Re(δVₘ)·(ω·Cₚ·R_{L})⁻¹

where Re(δVₛ) and Im(δVₛ) are the real and imaginary components of the voltage, ω is an angular frequency of light modulation, Cₚ is the capacitance between sensor and the wafer, and C_{L} and R_{L} are the input capacitance and resistance, respectively, of the electronic detection system.

From the sign of the imaginary component, the conductivity type may be determined. If the measurement is calibrated for a p-type material, then the sign of the imaginary component will change if the material is n-type.

Using above relationships, the depletion layer width, W_{d}, is given by equation:

$${W}_{d} = \frac{{ɛ}_{s}}{q} \frac{ω \vert Im ( δ {V}_{s} ) \vert}{φ ( 1 - R )} \cdot ( 1 + {[ \frac{Re ( δ {V}_{s} )}{Im ( δ {V}_{s} )} ]}^{2} )$$

where φ(1−R) is the intensity of light absorbed in the semiconductor, q is the elementary charge, and εₛ is the semiconductor permittivity.

In addition to the space-charge capacitance, C_{sc}, the measurement of the surface photovoltage can be used to determine the surface charge density, Qₛₛ, the doping concentration, N_{sc}, and the surface recombination lifetime, τ, using the following relationships. The space charge capacitance, C_{sc}, is proportional to the reciprocal of the semiconductor depletion layer width, W_{d}, according to the relationship:

$${C}_{sc} = \frac{{ɛ}_{s}}{{W}_{d}}$$

where εₛ is the semiconductor permittivity. The density of space charge, Q_{sc}, is in turn described by equation:

Q_{sc}=qN_{sc}W_{d}

where q is an elementary charge and the net doping concentration in the space-charge region, N_{sc}, is positive in an n-type material and negative in a p-type material. In addition, since the surface charge density, Q_{sc}, is given by the expression:

Q_{sc}=−Qₛₛ

the surface charge density is easily determined from the space charge density.

Further, if an inversion layer can be created at the wafer surface, the depletion layer width, W_{d}, under inversion conditions is related to the net doping concentration, N_{sc}, according to the relationship:

$${W}_{d} = \sqrt{\frac{4 {ɛ}_{s} kT ln ( \vert {N}_{sc} / {n}_{i} \vert )}{{q}^{2} \vert {N}_{sc} \vert}}$$

where kT is the thermal energy and nᵢ is the intrinsic concentration of free carriers in the semiconductor.

Finally, in the case of ion implanted silicon wafers, it is found that, especially in as-implanted conditions, carrier lifetime is inversely proportional to implant damage. In very low dose implanted cases, free carrier concentration is reduced. With heavy dose implant application, increased crystal damage gives a photovoltage signal dominated by photo carrier lifetimes rather than free carrier concentration. In some cases carrier lifetime is the dominant factor in the measured SPV signal. After the wafers are annealed, the substitutional site implanted dopant contributes to the net carrier concentration, N_{sc} which is derived from SPV. For as-implanted p or n-type wafers the charged defects density is a measure of implant dose/energy. For implanted/annealed silicon wafers the measured quantities give the doping concentration, which is directly correlated to implanted dose/energy.

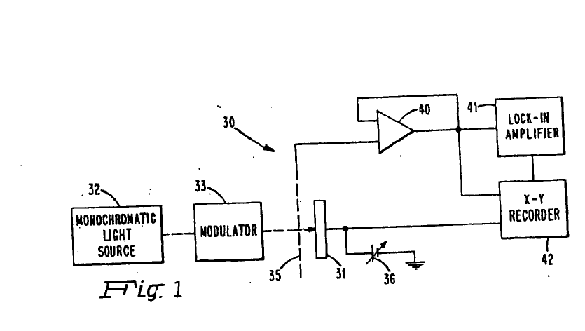

FIG. 1 illustrates an embodiment of an apparatus 30 for measuring the photo-induced voltage at the surface of a specimen 31 of semiconductor material. The apparatus includes a source of monochromatic light 32, typically a laser and an arrangement for controlling the intensity of the light output. The beam of light is directed through a modulator 33 to impinge on a region of the specimen 31. The modulated light impinges on and passes through a partially transmissive conductive reference electrode 35 which is spaced from the specimen 31 by an insulating medium such as a gas or a vacuum. The specimen 31 is connected through an adjustable DC biasing source 36 to ground. The reference electrode 35 is connected to the input of a high input impedance buffer amplifier 40. The output of the buffer amplifier 40 is connected to a lock-in amplifier 41. The outputs of the buffer amplifier 40 and the lock-in amplifier 41 and the specimen 31 are connected to an X-Y recorder 42.

The high dose implantation (>1×10¹⁶ at/cm²) of hydrogen, helium or a hydrogen/helium mixture is used primarily for manufacturing of the SOI structures. The characteristic crystalline damage associated with this process differs, both quantitatively and qualitatively, from the type of damage induced by the species traditionally used in silicon-chip process technology. The quantitative difference is related to the small atomic mass of the hydrogen atom that makes the number of implanted ions comparable to the number of implant-induced defects. As a result, modeling of the hydrogen-induced crystalline damage would be incomplete without taking into account interstitial hydrogen atoms. Significant qualitative difference is related to the types of dominant defects and their dependencies on the implant conditions.

In contrast to lower dose implants where a direct correlation exists between the concentration of point defects and the implanted dose, the typical SOI implant process (H₂ dose ranges from 2×10¹⁶ to 1×10¹⁷ at/cm²) has a density of crystalline point defects that do not correlate to the implant dose. The major characteristic defects created in this process are the (point defect) vacancy-hydrogen complexes, with the number of vacancies and hydrogen atoms in each complex varying from 1 to 4. The density of these defects, especially of the multi-vacancy complexes, is proportional to implant dose and very sensitive to the thermal budget. That is, even low temperatures ˜100° C. can change the defect complex configuration.

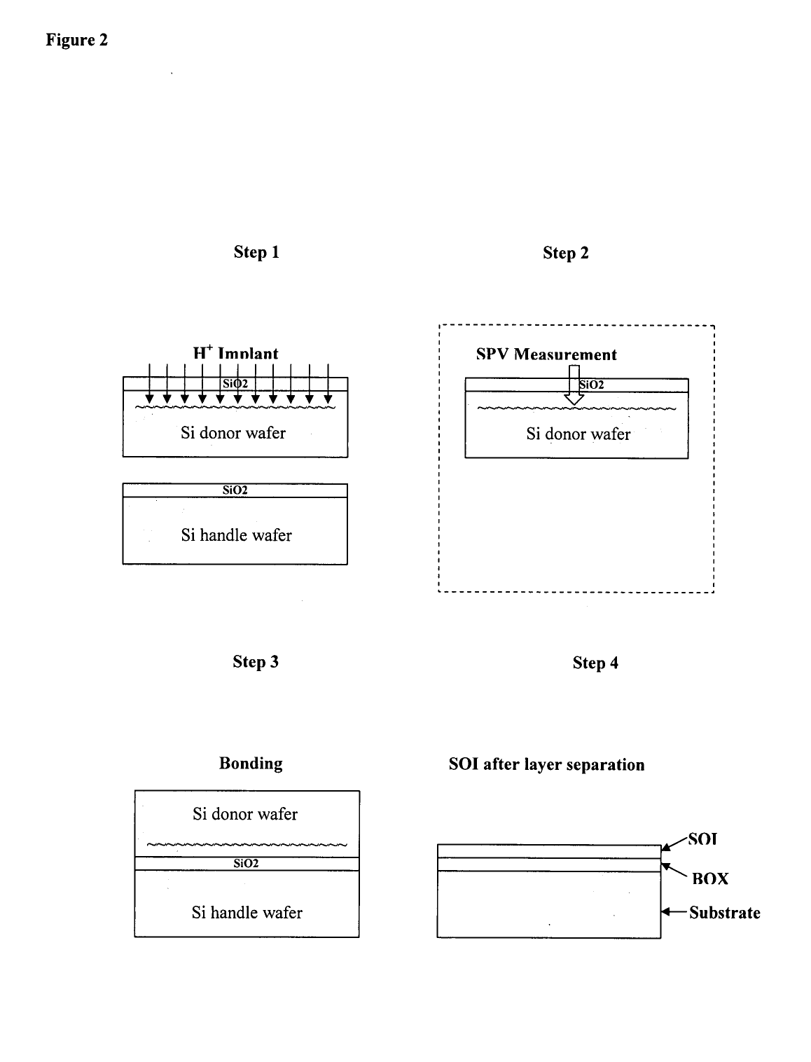

Referring to FIG. 2, a method of characterization of ion implanted semiconductor wafer during Smartcut™ SOI manufacturing process is illustrated. Ion (hydrogen, helium, or a combination of hydrogen/helium) implantation is an integral step in manufacturing of layer transfer or “bonded” SOI structures—characteristic of layer transfer techniques (Step 1). Other SOI or engineered substrate fabrication techniques are available and include, but are not limited to the following, Smartcut™, NanoCleave™, and Eltran™. The proposed non-contact photoelectric measurement method is based on ac-SPV technology (Step 2). This aspect of the invention allows monitoring of implant characteristics of a donor wafer through the SiO2 surface oxide following the implantation step, but before the wafer-bonding step (Step 3). The ion implantation step leads to formation of a weakened layer that is stressed to cause separation of the thin silicon film from a thick substrate donor wafer (Step 4). Therefore, it is critical to control the implant ion concentration across an entire wafer to ensure proper separation.

The application of an ac-SPV technique to the monitoring of the hydrogen-implanted semiconductor requires different physical model and algorithm than for other traditional wafer applications. Specifically, the electron hole pairs induced by light generate photo-voltage signals at the surface and implant/substrate interfaces. The surface photo-signal in implanted p-type silicon is reduced due to the effect of electrical neutralization of doping ions by implanted hydrogen. However, the interface related photo-voltage in case of the hydrogen implant can be strong enough due to the relatively high hydrogen density and characteristic property to concentrate around vacancies and dopants creating charged areas.

In high frequency light modulation, a photo-voltage associated with implant/substrate interface is inversely proportional to a net charge density. In the implanted case, with a non-uniform depth profile of charge associated with implant defects a net charge density (Qₙₑₜ) is measured in the implanted region rather than Q_{sc}. Qₙₑₜ is a Q_{sc} measured throughout the SOI depth. V_{PV}≈kTΦ/ωQₙₑₜ, where Φ is a light flux, T is temperature of the wafer, and ω is a light modulation frequency. In one embodiment, the modulation frequency is 33 kHz, with low intensity ultraviolet irradiation at room temperature. As illustrated by FIGS. 3 and 4, the dynamic charge is proportional to the density of characteristic defect complexes, which is in turn proportional to the implanted dose.

Furthermore, the spatial distribution of the characteristic defect complexes is correlated to implant energy and angle. Therefore, by measuring the dynamic charge the method allows key implant process parameters to be monitored. The important conditions of the measurement protocol include control of temperature during implantation and measurement processes and optimization of the probing light wavelength and intensity. The temperature control is critical due to the low activation energy of hydrogen in silicon. That is, higher temperatures may result in re-distribution of hydrogen ions and change in the net charge density. The optimization of the probing light intensity is driven by two requirements: signal linearity and signal strength (signal-to-noise ratio). The selection of the proper light energy is related to the light absorption profile of the material. Due to the presence of defect-related electric fields, a significant amount of photo carriers must be generated in the vicinity of the peak of the distribution of implanted ions in order to contribute to the interface photo-voltage.

Variations, modifications, and other implementations of what is described herein will occur to those of ordinary skill in the art without departing from the spirit and scope of the invention as claimed. Accordingly, the invention is to be defined not by the preceding illustrative description but instead by the spirit and scope of the following claims.

What is claimed is:

1. A method of characterizing implanted ion concentration in an engineered donor wafer comprising the steps of:
illuminating the engineered donor wafer using a modulated light source;
performing a non-contact SPV measurement on the silicon wafer;
measuring a dynamic charge (Q_{d}) in response to implant induced crystal damage; and
determining the accuracy and uniformity of the value of an implant parameter in response to the dynamic charge.

2. The method of claim 1 wherein the engineered donor wafer is a silicon-on-insulator wafer.

3. The method of claim 1 wherein the ion is selected from the group consisting of hydrogen, helium, argon, silicon, germanium and oxygen.

4. The method of claim 1 wherein the ion is an ion used for the bond and cleave technique.

5. The method of claim 1 wherein the implanted wafer is measured through a layer selected from the group consisting of a surface oxide layer, a nitride layer and a photo-resist layer.

6. The method of claim 1 wherein the implant parameter is selected from the group consisting of implant dose, energy and angle.

7. The method of claim 1 wherein the step of determining utilizes the equation V_{PV}ΩkTΦ/ωQₙₑₜ where V_{PV} is photo voltage generated in the implanted wafer, Φ is a light flux of the modulated light source, T is temperature of the wafer, and ω is a light modulation frequency of the modulated light source.

8. The method of claim 1 wherein the implant parameter is uniformity and the method further comprises a step of measuring the thermal effects of implant process non-uniformities.

9. A system for characterizing implanted ion concentration in an engineered donor wafer, the system comprising:
a modulated light source adapted to illuminate the engineered donor wafer;
a SPV measurement component adapted to perform a non-contact SPV measurement on the silicon wafer;
a charge measurement component adapted to measure a dynamic charge (Q_{d}) in response to implant induced crystal damage; and
a processor adapted to determine the accuracy and uniformity of the value of an implant parameter in response to the dynamic charge.

10. The system of claim 9 wherein the engineered donor wafer is a silicon-on-insulator wafer.

11. The system of claim 9 wherein the engineer donor wafer is illuminated before being subjected to a bond and cleave process.

12. The system of claim 9 wherein the ion is selected from the group consisting of hydrogen, helium, argon, silicon, germanium and oxygen.

13. The system of claim 9 wherein the implanted wafer is measured through a layer selected from the group consisting of a surface oxide layer, a nitride layer and a photo-resist layer.

14. The system of claim 9 wherein the implant parameter is selected from the group consisting of implant dose, energy and angle.

15. The system of claim 9 wherein the processor determines the accuracy and uniformity of the value of the implant parameter by utilizing the equation V_{PV}≈kTΦ/ωQₙₑₜ where V_{PV} is photo voltage generated in the implanted wafer, Φ is a light flux of the modulated light source, T is temperature of the wafer, and ω is a light modulation frequency of the modulated light source.

16. The system of claim 9 wherein the processor measures the thermal effects of implant process non-uniformities.

17. A system for characterizing implanted ion concentration in an engineered donor wafer, the system comprising:
means for illuminating the engineered donor wafer;
means for performing a non-contact SPV measurement on the silicon wafer;
means for measuring a dynamic charge (Q_{d}) in response to implant induced crystal damage; and
means for determining the accuracy and uniformity of the value of an implant parameter in response to the dynamic charge.

18. The system of claim 17 wherein the ion is selected from the group consisting of hydrogen, helium, argon, silicon, germanium and oxygen.

19. The system of claim 17 wherein the implanted wafer is measured through a layer selected from the group consisting of a surface oxide layer, a nitride layer and a photo-resist layer.

20. The system of claim 17 wherein the implant parameter is selected from the group consisting of implant dose, energy and angle.

21. The system of claim 17 wherein the means for determining the accuracy and uniformity of the value of the implant parameter utilizes the equation V_{PV}≈kTΦ/ωQₙₑₜ where V_{PV} is photo voltage generated in the implanted wafer, Φ is a light flux of the modulated light source, T is temperature of the wafer, and ω is a light modulation frequency of the modulated light source.

22. The system of claim 17 wherein the means for measuring measures the thermal effects of implant process non-uniformities.
